(19) United States
(12) Patent Application Publication
(10) Pub. No.: US 2025/0189564 A1
(43) Pub. Date: Jun. 12, 2025

(54) All Fiber Electro-Optical Voltage Sensor for Electrical Switchgear

(71) Applicant: Adam Jon Zbinden, Kenmore, WA (US)

(72) Inventor: Adam Jon Zbinden, Kenmore, WA (US)

(73) Assignee: OpticAmpere LLC, Kenmore, WA (US)

(21) Appl. No.: 19/054,849

(22) Filed: Feb. 16, 2025

(51) Int. Cl. G01R 15/24; G01R 1/07; G01R 31/327

(52) U.S. Cl. CPC G01R 15/243; G01R 1/071; G01R 15/247; G01R 31/3274

(57) ABSTRACT

An all fiber optic electric field sensor for indoor switchgear phase conductor bus bar voltage sensing, which is galvanically isolated from the electric circuit of the switchgear power distribution system, featuring a single mode optical transmitter, installed on the front side of a switchgear cubicle, which connects via an optical patch cord routed in conduit to a passive, in-line, all fiber polarization filtering module installed on the back of the switchgear cubicle, which connects to an all dielectric single mode fiber optic voltage sensor cable with standardized Kerr constant, routed within insulating all dielectric rigid conduit, which is secured with mechanical support brackets, featuring integrated vibration dampers, which traverses an optical path in parallel with a phase conductor bus bar and a ground bus, and where the degree of electric field induced birefringence occurring on the optical path which is perpendicular to the electric field radiating from the phase conductor is measured by observing the phase shift occurring in the orthogonally polarized modes during traversal of the single mode electro-optical voltage sensor cable perpendicular to the electric field, where an output of the sensor cable is analyzed with a 1×2 polarization maintaining fiber coupler which divides the polarized optical signal power equally to measure the preponderance of right circular polarized light over left circular polarized light, with the difference in optical intensity observed at the photodiodes proportional to the phase shift which varies exponentially with the electric field potential as an inverse function of linear distance from the phase conductor.

### BACKGROUND OF THE INVENTION

Voltage sensing in low and medium voltage switchgear is required for power system protection and control. The voltage is specified on a per unit basis which defines the normal electrical system operating parameters. ANSI elements 27 and 59 monitor under and over voltage conditions which, when asserted, trip protective circuit controls into an open state, for protection and control of the electrical power system. Voltage sensors in 480V power distribution switchgear are comprised of #12 SIS wires tapped directly to the copper bus bars, with wire leads brought out directly to electromagnetic transformers which step down the voltage to a level which can be digitally sampled as an input to digital microprocessor relays. At medium voltage, such as 12.5KV, the voltage sensing requires draw-out potential transformers which connect to the copper bus bars on the primary H1/H2 side of the potential transformer, and where the stepped down voltage on the secondary X1/X2 terminals of the potential transformer (PT) are tapped with #12 SIS wire and stepped down to digital logic voltage levels which can be sampled with an analog to digital (A/D) conversion card as an input to the backplane of a digital microprocessor relay.

In the former case of #12 SIS wire tapped directly to 480V bus, these leads may be wired directly into meters or relays, where the step-down voltage transformation to analog voltage levels for digital sampling occurs, without intermediate fusing or circuit breakers, such that the leads always remain energized, which poses a safety issue for maintenance or troubleshooting, as the sensor wires remain hot when disconnected as long as the bus is live. In many instances it is required to troubleshoot SCADA circuits without taking an outage, and this presents a problem if the voltage sensing leads require testing or reconfiguration as they are unable to be de-energized independently of the main bus where the sensing leads are connected.

In the case of draw out potential transformers in medium voltage switchgear, the instruments are heavy, mechanically prone to jamming, and occupy valuable space in the switchgear cubicle layout which could be used by additional feeders or instrumentation if alternative voltage sensing means with reduced form factor were available.

It is therefor desirable to provide a means of observing voltage, in the form of electric field potential, which does not require analog induction transformers and which is galvanically isolated such that testing or troubleshooting the voltage sensing circuit does not risk electrical energy exposure from the main bus. The present invention teaches an optical voltage sensor for indoor low and medium voltage switchgear which is galvanically isolated from the electrical power distribution system and which does not require the large iron cores and copper windings of potential transformer (PT) drawers.

The Kerr effect describes the polarization dependent phase shift exerted on orthogonally polarized modes traversing a perpendicular path relative to an electric field. The S and P orthogonally polarized modes experience different indices of refraction which produces linear birefringence which varies exponentially based on the electric field potential as an inverse function of linear distance from the electric field source comprised of the bus bar conductor, as modulated by the Kerr constant which describes the magnitude of electric field induced birefringence, which for fused silica glass, such as standard SM telecom fiber, is 0.053 (10⁻¹⁴ mV⁻²) at a wavelength of 633 nm.

$$Δ n = {n}_{P} - {n}_{S} = \overline{n} {KE}^{2} \qquad Eq . 1$$

Where the birefringence induced by an electric field E is described as Δn, the difference between the observed refractive indices of the parallel and perpendicular polarized modes when traversing a perpendicular path to an electric field, E, and where the Kerr constant, K, correlates the degree of birefringence observed, based on the average of the S and P refractive indices, inversely proportional to the square of the electric field potential, E.

The present invention measures the phase shift experienced by two orthogonally S and P polarized modes of equal amplitude, after traversing a perpendicular path to the electric field radiating from a phase conductor bus bar.

In the present invention, an optical pulse linearly polarized at 45° is transmitted along an all dielectric fiber optic cable, routed within rigid insulating dielectric conduit, in parallel with a bus bar phase conductor, and in parallel with respect to the ground bus and switchgear ground potential, and where the phase shift resulting from the birefringence induced by the perpendicularly oriented electric field radiating from the phase conductor is analyzed at a receiver by splitting the polarized optical pulse equally and filtering through circular polarizers which measure the amounts of right and left circularly polarized light, and where the difference in the intensity measurements transduces the degree of phase shift experienced by the linearly polarized, in phase, equal amplitude orthogonal modes which traverse a perpendicular path through the electric field, E.

For linearly polarized light, the Stokes parameter S3, which describes the preponderance of right circularly polarized light over left circularly polarized light, is null, as the phase angle & between the modes, which describes the phase shift, is initially zero, for light which is linearly polarized at 45°, and only after a phase shift & occurs and the linear polarization becomes elliptical does S3 become observable:

$${S}_{3} = 2 {E}_{0 x} {E}_{0 y} sin δ \qquad Eq . 2$$

From Equation 2, observations of S3 directly measure the phase delay, δ, between the orthogonally polarized modes, which is directly proportional to the electric field induced birefringence, and when modulated by the Kerr constant K, the observed intensity difference varies exponentially with the electric field potential, E, according to Equation 1 as an inverse function of observation distance from the electric field source.

### SUMMARY OF THE INVENTION

An optical transmitter module, comprised of a single mode laser transmitter connected to a DC power supply, with adjustable modulation rate, is mounted on the front side of the interior of a switchgear cabinet, and transmits via single mode fiber optic patch cord to a linearly polarizing optical module mounted and installed proximate the phase conductor bus bar, on a back side of the switchgear cubicle where voltage is being measured, and the output of the linear polarizer optical module connects to an all dielectric single mode fiber optic sensor cable, housed within rigid insulating dielectric conduit, which is mounted parallel to the bus bar with an insulating bracket with integrated vibration dampers, and the dielectric single mode fiber optic sensor cable traverses a perpendicular path relative to the electric field radiating from the phase conductor bus bar, with respect to the ground potential established by the ground bus within the switchgear cubicle which connects to the switchgear ground grid network, and the phase-shifted orthogonally polarized modes which are outputs of the fiber optic voltage sensor cable routed within rigid conduit in parallel with the bus bar conductor connects with a polarization analyzer module, which splits the signal via a 1×2 polarization maintaining fused fiber coupler, or a PLC silicon splitter chip as used in passive optical networks (PON), with each half of the divided signal routed to polarizing filters with output intensities dependent on the amount of right and left circularly polarized light generated by the phase shift, and where the difference in the output intensities is a direct measurement of the Stokes parameter S3, from which the phase delay δ and electric field induced birefringence is directly calculated with Equation 2, which varies exponentially with the electric field potential, as an inverse function of electro-optical interaction distance from the electric field source, as modulated by the Kerr constant for the waveguide material of the single mode fiber optic cable sensor, based on Equation 1.

### DESCRIPTION OF THE FIGURES

FIG. 1 depicts the optical voltage sensor configuration within a typical switchgear cubicle section where voltage is being observed on a bus bar conductor, where 1 is an optical transmitter module, comprised of a single mode laser source, which connects via single mode fiber optic patch cord routed within the switch gear to a linearly polarizing optical module 2 which is installed within the switchgear cubicle proximate to the phase conductor bus bar 6, where a linear 45° degree polarized light output from 2 is an input to 4, an all fiber electro-optical single mode cable sensor with a standardized Kerr constant routed within a rigid insulating conduit, which is secured in parallel relative to a phase conductor bus bar conductor 6 with an insulating dielectric bracket 3 which mechanically secures the fiber optic sensor cable and conduit 4 which is routed in parallel with respect to the bus bar 6 and the ground bus 10, such that the equal amplitude, linearly polarized and in-phase S (perpendicular) and P (parallel) modes transmitted from 2 traverse a perpendicular path relative to the electric field radiating from the phase conductor bus bar 6 with respect to ground potential at 10, and where another insulating dielectric bracket 5 transitions the fiber optic cable sensor and conduit from the region where the electric field is being sensed back to a polarization analyzer mounted on an opposite section of the switchgear cubicle interior, where the analyzer is comprised of a 1×2 polarization maintaining splitter 7, which transmits to a polarizing filter module 8, comprised of quarter wave plates followed by +45° and −45° linear polarizers, respectively, which reject right and left circularly polarized light to transduce their intensity, as the output intensity of 8 will vary in direct proportion to the amount of right and left circularly polarized light present in the polarized optical pulses divided at 7, and the photo diodes 9 produce an output current proportional to the optical intensity generated by the polarization analyzing filters 8, and where the photo detecting module 9 has auxiliary communication port connections to transmit the transduced optical intensity measurements to external SCADA networks, such as the back planes of digital microprocessor relays installed separately within the switchgear.

FIG. 2 depicts the present invention configured to measure voltage on a typical switchgear bus bar, where 1 is an optical transmitter module comprised of a single mode fiber coupled laser source with output port connecting to an insulated polarizer reference module 3 which attaches to a bus bar conductor 2 which is installed within the switchgear 8. The output of the insulated linear polarizer reference module 3 features a port which connects to an insulated conduit which contains electro-optical fiber optic sensor cable 5 which is routed in parallel with the conductor bus bar 2 and the ground bus 4. The output of the acoustically insulated electro-optical sensor cable 5 connects to a circularly polarizing filter module 6 which contains a polarization maintaining 1:2 optical splitter, and right and left circular polarizing filters which measure the phase delay angle of the orthogonally polarized optical modes output from the linear polarizer reference module 3 after the in-phase equal-amplitude modes traverse a linear path along 5 in parallel with the electric field radiating from 2 and the ground potential established at 4, where the output of 6 is transmitted in a deterministic manner to an optical intensity detector module 7, which contains photo-diodes and programmable logic controller chipset to calculate the electric field strength, and voltage, based on the observed degree of linear birefringence at the output of 5 and as transduced by 6, using Equations 1 & 2, and where 1 and 7 are networked for external communications through auxiliary ports connected with programmable logic controller chipset outputs.

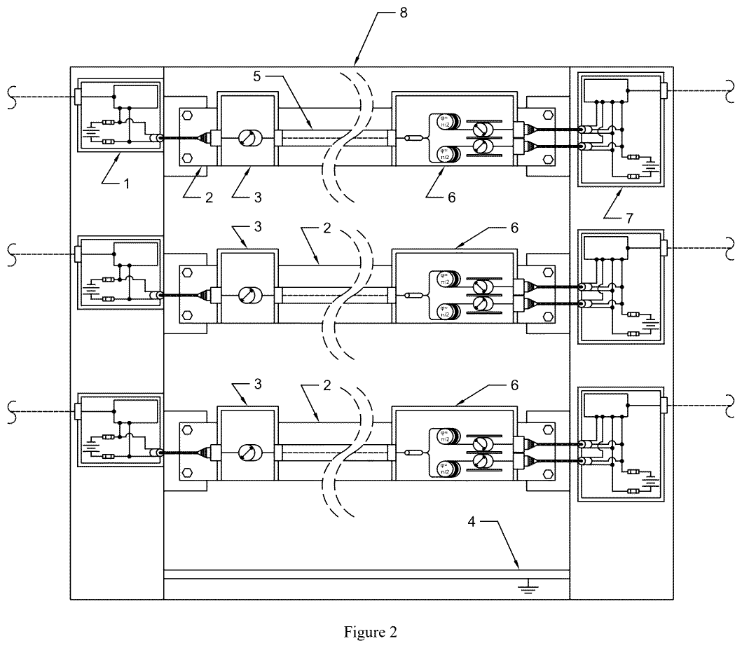

### DETAILED DESCRIPTION OF THE INVENTION

It will be obvious to one skilled in the art field of the present invention that the optical transmitter comprised of a single mode laser and photo-diode photo-detector modules may be integrated directly proximate to a SCADA I/O concentrator back-plane, while the polarizing filter which provides the linearly polarized 45° reference input, and the 1×2 polarization maintaining optical splitting and phase shift measuring polarization filtering modules, may be installed directly proximate the input and output of the fiber optic cable sensor which traverses a parallel path relative to the phase conductor bus bar and ground bus bar, perpendicular to the electric field with respect to ground potential, where the input and output transitions are demarcated by the dielectrically insulating and vibration dampening mechanical support brackets which secure the Kerr-effect sensing fiber optic cable and conduit perpendicular to the electric field radiating from the phase conductor bus bar, with respect to ground potential.

The fiber optic cable sensor will be jacketed and insulated mechanically to dampen any potential for vibration within the outer rigid conduit, while the mechanically insulating brackets incorporate damping to eliminate the transfer of any acoustic vibration from the environment to the cable sensor during normal operation, such that the linear birefringence of the Kerr effect fiber optic cable sensor is insulated from acoustic disturbances and therefor only transduces the birefringence induced by the electric field and which is described by Equation 1.

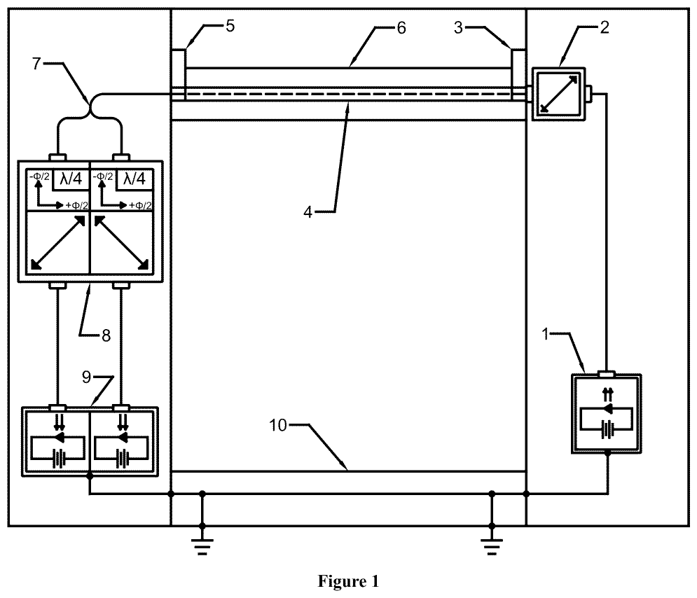

In the event of abnormal seismic events, such as would occur during an earthquake, or any other environmental event producing acoustic waves of magnitude which would render the sensor blind due to the overwhelming acoustic noise observed at the analyzer, the abnormal birefringence signal which is generated by such a seismic event shall be programmed to automatically trip all protective circuit devices via the connected SCADA controls, as though a fault had occurred, since in the case of environmental catastrophes such as earthquakes, where structures may be expected to fail, the de-energization of circuits is a necessary safety measure to prevent unintended incident energy exposure and electrocution hazards. As the polarization filtering occurs proximate the fiber optic cable sensor where the electro-optical phase shifting Kerr effect is observed in the presence of the electric field radiating from energized bus bar within the switch gear, the use of polarization maintaining fiber is not required, and single mode fiber may be used for all patch cord links between modules as shown in FIG. 1. The patch cords shall be routed in conduit or micro duct such that the fiber optic cables are insulated from vibration and are all dielectric to be electrically non-conductive with respect to proximate electric fields.

The fiber optic cable sensor waveguide material may be fused silica, flint glass, or alternatively doped to manipulate the Kerr constant, however the present invention claims all such embodiments including standard fused silica glass with Kerr constant of 0.053 (10⁻¹⁴ mV⁻²).

FIG. 1 is not drawn to scale and is enlarged to show the optical polarization schematic. In the preferred embodiment, the polarization module is comprised of an in-line all fiber linear polarizer with a high extinction ratio, and the analyzer is comprised of a polarization maintaining 1×2 fiber coupler and additional in-line fiber polarizers, and where the quarter-wave plate retarding polarizing element is produced by coiling a section of single mode fiber around a mandrel structure with a bending radius tuned to produce a refractive index difference for S and P orthogonal modes yielding quarter wave phase retardance prior to the linear polarizer splice point in the analyzer circuit.

The passive optical filtering modules connected to the input and output of the Kerr effect sensing fiber optic cable, which is mounted in parallel with respect to the phase conductor bus bar and ground bus bar, may be mounted on the back side of the switch gear cubicle panel, with direct outputs connecting via the insulating mounting brackets which position the fiber optic cable sensor and conduit relative to the bus bar, while the single mode laser transmitter and associated power supply, and the photo-diode optical photodetector where optical intensity measurements proportional to the electric field induced birefringence are measured, may be mounted and installed on the front side of the switch gear cubicle section where the bus voltage is being optically measured, in a preferred installation embodiment. With no voltage applied to the phase conductor bus bar, with respect to the ground bus potential, some characteristic amount of linear birefringence will exist in the single mode fiber optic Kerr-effect electric field sensing circuit, and this will be observed at a zero-energy condition for calibration. For alternating current measurements, this zero-voltage linear birefringence characteristic magnitude for the optical voltage sensing network will re-occur at every zero-crossing, with the observed phase delay resulting from linear birefringence induced by the electric field increasing and decreasing concomitantly with the rise and fall of the sinusoidal voltage waveform, and as the polarized optical pulses are modulated with a much higher frequency than the fundamental electrical power frequency, a hypothetical 100 megabit per second optical pulse rate samples each voltage cycle wave form at rate of 1,666,666 samples per 60 HZ electrical wave cycle, which more than guarantees accurate sampling of the 60 HZ fundamental frequency of the electrical field wave form being optically measured, per the 2× sampling rate requirement stipulated by the Shannon-Nyquist sampling theorem to avoid aliasing in the sampled signal. Such a well-oversampled optical sensor frequency also offers digital harmonic waveform analysis potential with the discrete Fourier transform.

1. An all-fiber optic electric field sensor for measuring voltage on an indoor switchgear phase conductor bus bar, comprising:
a single mode laser transmitter which emits constant power at a calibrated center wavelength, connected to a direct current power supply featuring an adjustable modulation rate;
an optical connection from said optical transmitter to a passive polarization filtering module, comprised of a linear 45° degree in-line all fiber optic polarizer, which produces linearly polarized orthogonal in-phase modes of equal amplitude;
an all dielectric single mode fiber optic current sensing cable, routed within an all dielectric rigid insulating conduit, which is secured in parallel with a phase conductor bus bar with an insulated mechanical support bracket with an integrated vibration damper, at an input of said fiber optic voltage sensor cable, which receives an output from said linear 45° polarizer module, and where said fiber optic electric field sensor cable traverses a path perpendicular to an electric field radiating from said bus bar, while maintaining a parallel orientation with respect to said phase conductor bus bar and a ground bus connected to a switchgear ground grid, and where an output of said fiber optic electric field sensor cable, which defines a length of the electric field sensor cable and conduit within the switchgear, and an effective electro-optical interaction path length, relative to the input, is secured with a second mechanical support bracket featuring vibration dampers inside a switchgear cubicle where said fiber optic electric field sensor cable is routed;
a passive polarization filtering module, which analyzes a phase-shifted polarized optical output, comprising a polarization maintaining 1×2 splitter with 50:50 optical power distribution, where a first half of the divided signal is transmitted through a right circular polarizing filter, and a second half is transmitted through a left circular polarizing filter;
a photo-detector module, comprised of photodiodes which produce an output current proportional to the incident optical intensity transmitted orthogonally from said right and left circular polarizing filters, and where a difference in observed optical intensity magnitudes is proportional to the phase shift of the linearly polarized modes which occurs during traversal of the fiber optical voltage sensing cable on an optical path perpendicular to the electric field radiating from the phase conductor bus bar where voltage is being observed, where said phase shift resulting from electro-optically induced linear birefringence varies exponentially with the electric field potential which radiates from said bus bar as an inverse function of linear distance from said electric field, modulated by the standardized Kerr constant of the electro-optical single mode voltage sensor cable; and, communication ports from said photo-detector module which transmit an electrically transduced optical phase shift observed at the polarization filtering analyzer module to a digital microprocessor relay back plane for SCADA network integration.
